(19) United States
(12) Patent Application Publication
(10) Pub. No.: US 2011/0061703 A1
(43) Pub. Date: Mar. 17, 2011

(54) HEAT RECOVERY SYSTEM FOR THE HOT ROLLING LINE

(75) Inventor: Hiroyuki IMANARI, Chiba-shi (JP)

(73) Assignee: TOSHIBA MITSUBISHI-ELECTRIC INDUSTRIAL SYS.CORP., Tokyo (JP)

(21) Appl. No.: 12/620,724

(22) Filed: Nov. 18, 2009

(30) Foreign Application Priority Data
Sep. 17, 2009 (JP) 2009-215735

(51) Int. Cl. H01L 35/30

(52) U.S. Cl. 136/205

(57) ABSTRACT

A heat recovery system for a hot rolling line where a metallic material is heated and rolled, the system includes a thermoelectric converter converting heat generated by processing of the metallic material at the hot rolling line to electricity, and an electricity storage storing the electricity converted by the thermoelectric converter.

### CROSS REFERENCE TO RELATED APPLICATIONS AND INCORPORATION BY REFERENCE

This application is based upon and claims the benefit of priority from prior Japanese Patent Application P2009-215735 filed on Sep. 17, 2009; the entire contents of which are incorporated by reference herein.

### BACKGROUND OF THE INVENTION

1. Field of the Invention

The present invention relates to a heat recovery system for a hot rolling line where metallic materials are processed.

2. Description of the Related Art

Rolling lines of metallic materials include: hot rolling lines of thin plates, the rolling lines of thick plates and cold rolling lines for manufacturing steel plates; rolling lines of steel materials with various sectional shapes, bars, and wire rods; and aluminum and copper rolling lines. Among these rolling lines, the hot rolling lines consume a comparatively large amount of energy. This is because at the hot rolling lines, the metallic materials to be rolled are heated to high temperature to be softened and are then greatly deformed. Plants themselves for the hot rolling lines of thin plates and the hot rolling lines of thick plates are large and consume a large amount of energy.

Unfortunately, heat energy released from the metallic materials that are hot at the hot rolling lines cannot be recovered or reused enough. In each rolling step, the heat energy from the metallic materials due to radiation or convection just warms the surrounding air. Moreover, water used for cooling is recovered but is just cooled in the outside of the plants in many cases, and heat contained in the cooling water is hardly recovered and reused.

In recent years, in order to recover the heat contained in the cooling water, a cooling apparatus and a heat recovery system for a rolling line are proposed. For example, at an incineration plant operated by a local government, when heat generated by waste incineration can be used to heat water and obtain hot enough water or the like, the hot water can be vaporized and used to rotate a turbine for power generation in some cases. Moreover, water at a temperature of not higher than 100° C. is sometimes supplied to a public bath or the like adjacent to the incineration plant.

Even if the heat generated from the hot rolling line can be recovered, generally, it is difficult to reuse the recovered heat. If hot enough water is obtained, hot steam can be generated and used for power generation in some cases. However, reuse of heat is difficult particularly when the water or medium is not hot enough. Generally, as a form of energy, electricity is more flexible in use than heat except particular cases where heat is reused at a public bath or the like. The electricity is a form of energy difficult to store, but high-performance electricity storage devices such as secondary batteries have been developed recently.

### SUMMARY OF THE INVENTION

An aspect of the present invention inheres in a heat recovery system for a hot rolling line where a metallic material is heated and rolled. The heat recovery system comprises a thermoelectric converter converting heat generated by processing of the metallic material at the hot rolling line to electricity; and an electricity storage storing the electricity converted by the thermoelectric converter.

### BRIEF DESCRIPTION OF THE DRAWINGS

FIG. 1 is a schematic view showing a configuration of a heat recovery system according to a first embodiment of the present invention.

FIG. 2 is a schematic view showing an example of the arrangement of thermoelectric converters of the heat recovery system according to the first embodiment of the present invention.

FIG. 3 is a schematic view showing an example of the structure of each thermoelectric converter of the heat recovery system according to the first embodiment of the present invention.

FIG. 4 is a schematic view showing a configuration of a heat recovery system according to a second embodiment of the present invention.

FIG. 5 is a schematic view showing a configuration of a heat recovery system according to a third embodiment of the present invention.

FIG. 6 is a schematic view showing an example of the installation location of the heat recovery system according to the third embodiment of the present invention.

FIG. 7 is a schematic view explaining an operation of a heat pump.

FIG. 8 is a schematic view showing a configuration of a heat recovery system according to a modification of the third embodiment of the present invention.

FIG. 9 is a schematic view showing a configuration of a heat recovery system according to another modification of the third embodiment of the present invention.

FIG. 10 is a schematic view showing a configuration of a heat recovery system according to the fourth embodiment of the present invention.

FIGS. 11A and 1B are graphs showing examples of efficiency curves for determining the effectiveness of heat recovery by the heat recovery system according to the fourth embodiment of the present invention.

### DETAILED DESCRIPTION OF THE INVENTION

A first, second, third and fourth embodiments of the present invention will be described with reference to the accompanying drawings. In the following description of the drawings, the same or similar reference numerals are applied to the same or similar parts and elements.

The following embodiments just shows systems and methods to embody the technical idea of the present invention, and the technical idea of the present invention does not specify materials, shapes, structures, and arrangements of the constituent components and the like to the following description. The technical idea of the present invention can be variously modified in the scope of claims.

### First Embodiment

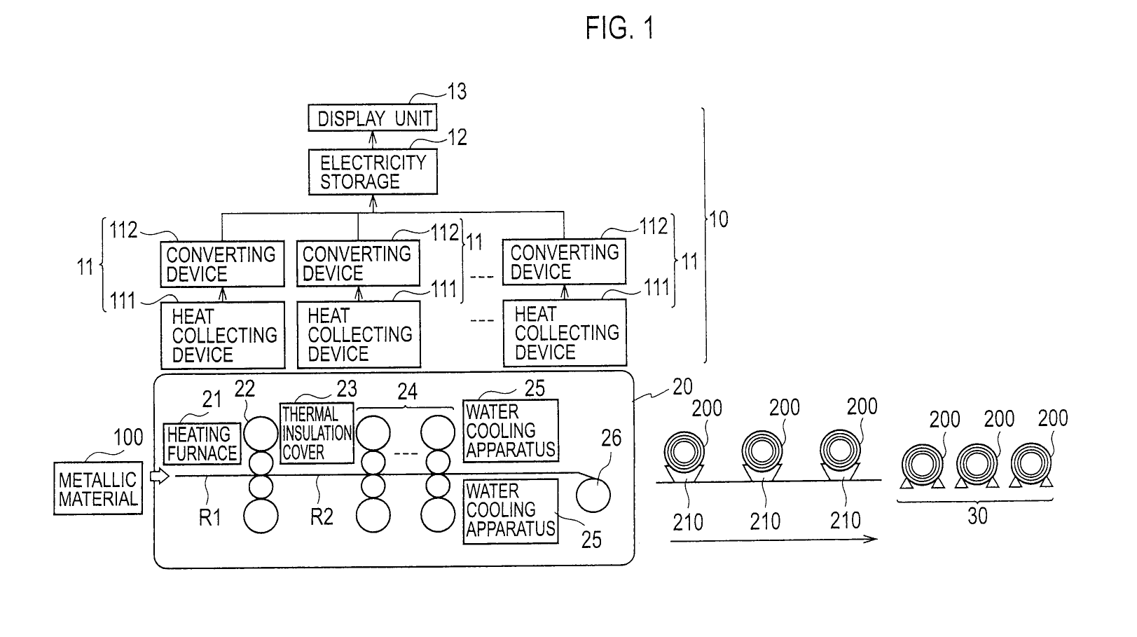

A heat recovery system 10 according to a first embodiment of the present invention recovers heat generated at a hot rolling line 20 where a metallic material 100 is heated and rolled. As shown in FIG. 1, the heat recovery system 10 includes: thermoelectric converters 11 converting heat generated by processing of the metallic material 100 at the hot rolling line 20 to electricity; and an electricity storage storing electricity converted by the thermoelectric converters 11. Each of the thermoelectric converters 11 includes: a heat collecting device 111 collecting heat generated from the metallic material 100; and a converting device 112 converting the heat collected by the heat collecting device 111 to electricity. The heat recovery system 10 further includes a display unit 13 displaying an amount of electricity stored in the electricity storage 12.

FIG. 1 shows an example of the configuration when the hot rolling line 20 is a hot rolling line of thin plates. At the hot rolling line 20 of thin plates, the metallic material 100 which is cuboidal and called a slab is heated in a heating furnace 21 and is then subjected to rolling at a roughing mill 22 for several times to manufacture a bar with a thickness of about 30 to 40 mm. The metallic material 100 changes its name to a bar, a strip, a plate, and the like each time the metallic material 100 is subjected to the rolling steps conducted at the hot rolling line 20, but hereinafter, the name of “metallic material” is used throughout all the steps.

The metallic material 100 rolled by the roughing mill 22 is conveyed to a finishing rolling mill 24. The path between the roughing mill 22 and finishing rolling mill 24 may be covered with a thermal insulation cover 23 so that the metallic material 100 does not cool down while being conveyed from the roughing mill 22 to the finishing rolling mill 24. The thermal insulation cover 23 may be configured to be opened. In order to keep heat, the thermal insulation cover 23 is closed to cover the conveying path. When the thermal insulation cover 23 is not used, the thermal insulation cover 23 is opened to expose the conveying path. The metallic material 100 is rolled by the finishing rolling mill 24 to a product thickness of about 1.2 to 12 mm.

Thereafter, water is poured onto the metallic material 100 by a water cooling apparatus 25 to cool the metallic material 100 before a winder 26. The metallic material 100 is finally wound by the winder 26, thus manufacturing product coils 200. After being removed from the winder 26, the product coils 200 are loaded on coil cars 210 and conveyed to a coil yard 30, which is a storage of the product coils 200. The product coils 200 are stored at predetermined places in the coil yard 30 until shipment. The product coils 200 are further subjected to cold rolling in some cases and are directly used in other cases, depending on the intended use thereof including building materials.

The temperature of the metallic material 100 at the hot rolling line of thin plates is typically 1200° C. to 1250° C. at the exit side of the heating furnace 21, 1100° C. to 1150° C. at the exit side of the roughing mill 22, 1050° C. to 1100° C. at the entry side of the finishing rolling mill 24, and 850° C. to 900° C. at the exit side of the finishing rolling mill 24. The coiling temperature of the metallic material 100 is 500° C. to 700° C. In order to obtain a high material quality, the coiling temperature is sometimes reduced to about 300° C.

In order to efficiently collect heat generated from the metallic material 100 which is heated to high temperature at the hot rolling line 20 as described above, preferably, the thermoelectric converters 11 of the heat recovery system 10 according to the first embodiment of the present invention are disposed at a close distance from the metallic material 100 which is conveyed along the hot rolling line 20.

The heat recovery system 10 includes one or a plurality of the thermoelectric converters 11. To keep a high efficiency, the converting device 112 is attached near the heat collecting device 111. Preferably, the heat collecting device 111 is disposed at: a place where there is no splashing water including a descaler; a place where the warpage of the metallic material 100 is small; a place where the metallic material 100 stays for a comparatively long time; a place where the metallic material 100 is hot; or the like. For example, the heat collecting device 111 is disposed: at the path through which the metallic material 100 is conveyed after coming out from the heating furnace 21 until reaching the entry of the roughing mill 22 (indicated by R1 in FIG. 1); or at a conveying table located between the roughing mill 22 and finishing rolling mill 24 (indicated by R2 in FIG. 1). In addition to the aforementioned places, the heat collecting device 111 can be disposed at any conveying table in the hot rolling line 20 which satisfy the aforementioned conditions, even at a short conveying table.

Accordingly, the places where the thermoelectric converters 11 are arranged are not limited to any one of the places R1 and R2 in FIG. 1 and may be disposed both of the places R1 and R2. The thermoelectric converters 11 may be also disposed in any places other than the places R1 and R2.

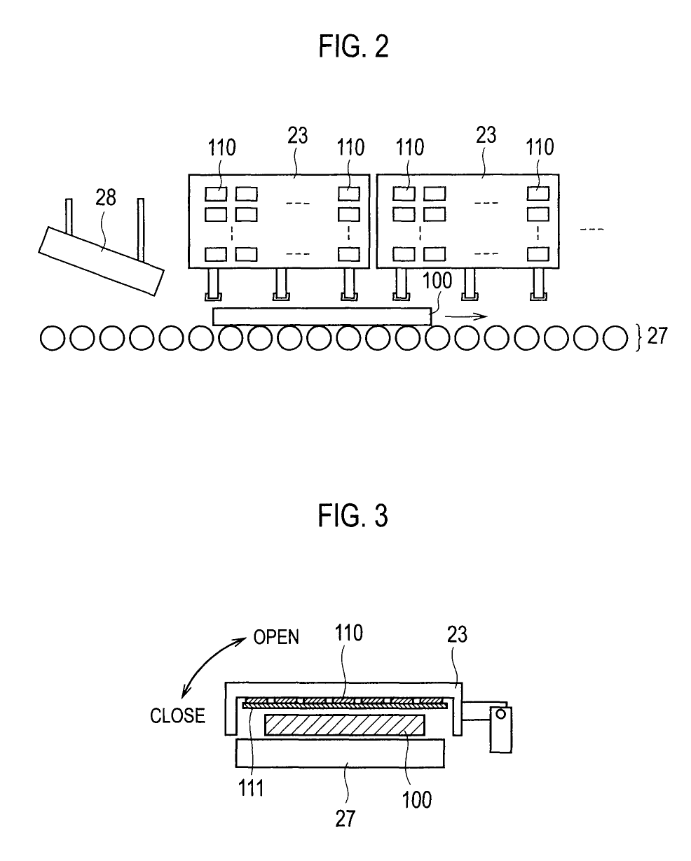

FIG. 2 shows an example of the arrangement of the heat collecting devices 111 and converting devices 112. The metallic material 100 is conveyed within the hot rolling line 20 by table rolls 27. Each of the thermal insulation covers 23 includes an opening/closing mechanism so as to cover the metallic material 100 loaded on the conveying table together with the conveying table. FIG. 2 shows the thermal insulation covers 23 which are opened. A warpage correcting unit 28 is provided at the entry side of the heat insulation covers 23 so as to prevent the warped metallic material 100 from colliding with the heat insulation covers 23 when the thermal insulation covers 23 are closed.

In the example shown in FIG. 2, a number of thermoelectric elements 110, each of which is a part of the corresponding one of the converting device 112, are attached within the thermal insulation covers 23. Accordingly, when the heat insulation covers 23 are closed, the metallic material 100 faces the thermoelectric elements 110. At this time, the distance between the metallic material 100 and the inner surface of the heat insulation cover 23 facing the metallic material 100 is about 300 mm to 500 mm, for example.

The metallic material 100 has a temperature of about 1100° C. just after being rolled by the roughing mill 22. Accordingly, some of the thermoelectric elements 110 could be damaged. Moreover, tightly arranging the thermoelectric elements 110 cannot be implemented in some cases because of the cost thereof. Accordingly, in order to protect the thermoelectric elements 110 and reduce thermal unevenness to provide a uniform distribution of heat, for example, as shown in FIG. 3, a heat collecting plate serving as the heat collecting devices 111 is placed so as to cover the thermoelectric elements 110. FIG. 3 is a cross-sectional view in a direction perpendicular to the conveying direction of the metallic material 100.

The inner surface of each heat insulation cover 23 which faces the metallic material 100 is made of a heat insulating material, for example, such as asbestos or glass fibers. This is for the purpose of preventing heat from the metallic material 100 from being transferred to the outside of the heat insulation covers 23. The heat collecting plate can be made of a material satisfying the following conditions:

(1) The material is resistant to heat from the metallic material 100, whose surface temperature is 1000° C. to 1100° C. at the position where the heat insulation cover 23 is installed.

(2) The thermal conductivity of the material is not small.

(3) The material easily absorbs heat and easily transfers heat to the thermoelectric elements 110.

To satisfy the condition (3), preferably, the material of the heat collecting plate has a low specific heat.

For example, general steel materials which averagely satisfy the above conditions (1) to (3) can be used as the heat collecting plate. On the other hand, copper has a large thermal conductivity, but the melting point thereof is not more than 1100° C., which does not satisfy the condition (1). Ceramic materials are unsuitable for the heat collecting plate because of the conditions (2) and (3).

Even in the place where the heat insulation covers 23 are not provided, by setting the thermoelectric elements 110 and the heat collecting plate so that the thermoelectric elements 110 and heat collecting plate cover the top of the conveying table with the same structure as the above structure, the thermoelectric elements 110 can catch heat at a temperature close to the temperature of the metallic material 100. It is therefore possible to efficiently convert heat to electricity. The thermoelectric elements 110 converting heat to electricity can be, for example, devices utilizing Seebeck effect. Such devices receive heat and produce voltage. The current thermoelectric conversion efficiencies of Seebeck devices are about 7% to 8%, and generally, the thermoelectric conversion efficiencies thereof increase as the ambient temperature increases like a quadratic curve.

The electricity converted from heat by the thermoelectric converters 11 as described above is stored in the electricity storage 12. The metallic material 100 passes by the thermoelectric converters 11 intermittently, and heat cannot be continuously converted to electric power. Accordingly, it is difficult to connect the heat recovery system 10 shown in FIG. 1 directly to a power system. The electricity storage 12 can be, for example, a secondary battery or the like. The amount of electricity stored in the power storage 12 is displayed by the display unit 13. This facilitates judging whether to connect the electricity storage 12 to the power system or whether to use the electricity storage 12 as the power source in the plant. The display unit 13 is a display where the amount of electricity is indicated in numerals or a graph, for example.

As described above, according to the heat recovery system 10 shown in FIG. 1, one or a plurality of the thermoelectric converters 11 are disposed near the hot rolling line 20, so that heat generated from the metallic material 100 due to at least one of the plurality of processing steps performed at the hot rolling line 20 can be converted to electricity. In other words, heat can be efficiently recovered from the hot metallic material 100 while the metallic material 100 is repeatedly conveyed and rolled between the heating furnace 21 and winder 26 of the hot rolling line 20.

For example, it is assumed that the metallic material 100 weighs 20 tons and has a specific heat of 0.15×4.19 (kJ/kg/° C.). If the metallic material 100 has a temperature of 1200° C. just after being taken out from the heating furnace 21 and is finally cooled to 600° C., the metallic material 100 loses 7,542,000 kJ of heat energy to the ambient air and cooling water. Cooling the metallic material 100 only by cooling water at 20° C. and heating all the cooling water to 100° C., not considering air cooling, requires 22,500 kg of cooling water (=7,542,000/4.19/(100−20)). In other words, 22.5 tons of boiling water is produced. Moreover, it is assumed that heat removed by air cooling or radiation is 30% of 7,542,000 kJ of heat energy. If 5% thereof can be recovered, 113,130 kJ (kWs) of heat energy can be converted to 31 kWh of electric energy. With 31 kWh of electricity, a small electric motor rated at 10 kW can be driven for about three hours under rated operation. Herein, the reason for assuming the recovery efficiency to be 5% is that, considering the peripheral devices and the like, it is sure that the total thermoelectric conversion efficiency is lower than the thermoelectric conversion efficiency of the thermoelectric elements 110 themselves, which is about 7% to 8%.

The aforementioned numerical example is a calculation for the single metallic material 100, and several tens or hundreds of the metallic materials 100 can generate an enormous amount of electric power. By improving the thermoelectric conversion efficiency of the thermoelectric elements 110, which is assumed to be 7 to 8% in the aforementioned example, it can be expected that more electricity will be obtained.

Although the hot rolling lines generate a lot of heat, generally, most of the heat is so-called low-quality energy which cannot be recovered at high temperature. For example, the temperature of the water which has cooled the metallic material is raised to several tens ° C., but it is very difficult to recover energy from water at several tens ° C. Generally, such energy used to be just released into the air.

In the heat recovery system 10 according to the first embodiment of the present invention, the thermoelectric converters 11 converting heat to electricity are disposed adjacent to the metallic material 100 conveyed along the hot rolling line 20 in order to convert heat generated from the metallic material 100 to electricity. It is therefore possible to efficiently recover the energy which used to escape into the air. According to the heat recovery system 10 shown in FIG. 1, it is possible to provide a heat recovery system which can efficiently recover heat generated from the metallic material 100 at the hot rolling line 20 and storing the same as electricity.

### Second Embodiment

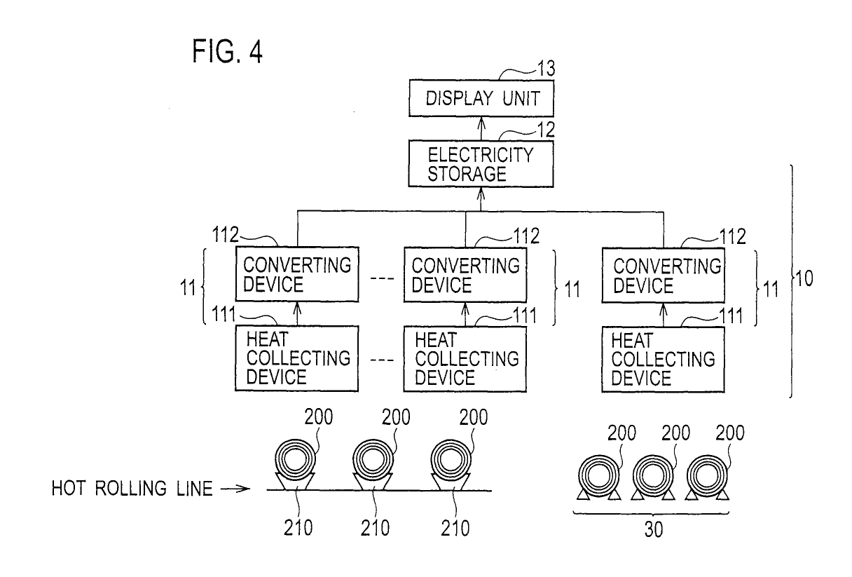

As shown in FIG. 4, a heat recovery system 10 according to a second embodiment of the present invention is different from the heat recovery system 10 of FIG. 1 in that heat of the product coils 200 manufactured by the hot rolling line 20 is recovered. The other configuration is the same as that of the first embodiment of FIG. 1.

At a path through which the product coils 200 taken out from the winder 26 and loaded on the coil cars 210 are conveyed to the coil yard 30, the heat collecting devices 111 and converting devices 112 are disposed in a similar manner to the conveying path within the hot rolling line 20 explained in FIG. 1. In the case where the heat collecting devices 111 and converting devices 112 are disposed at the path though which the product coils 200 are conveyed, unlike the case where the heat collecting devices 111 and converting devices 112 are disposed within the hot rolling line 20, there is no problems of water splashing and warpage of the metallic material 100, and moreover, the temperature thereof are comparatively low. Accordingly, there is less need to give a special consideration to the arrangement of the heat collecting devices 111. In some cases, the heat collecting devices 111 are unnecessary.

In the case of installing the thermoelectric converters 11 in the coil yard 30, the heat collecting devices 111 and converting devices 112 need to be installed for the product coils 200 which are still hot just after manufacture. Accordingly, the places where the hot product coils 200 are stored are determined, and the heat collecting devices 111 and conversion devices 112 are then disposed at the determined places. Alternatively, the heat collecting devices 111, conversion devices 112, and electricity storage 12 may be integrated and made movable to be used near the hot product coils 200.

The product coils 200 are as hot as 400° C. to 600° C. just after being removed from the winder 26, and the thermoelectric converters 11 can be easily disposed at a close distance from the conveying path of the product coils 200. The heat recovery system 10 according to the second embodiment can therefore perform efficient thermoelectric conversion. The thermoelectric converters 11 can be disposed at not only the path through which the product coils 200 are conveyed from the hot rolling line 20 to the coil yard 30 and in the coil yard 30 but also disposed within the hot rolling line 20. The others thereof are substantially the same as those of the first embodiment, and the redundant description is omitted.

### Third Embodiment

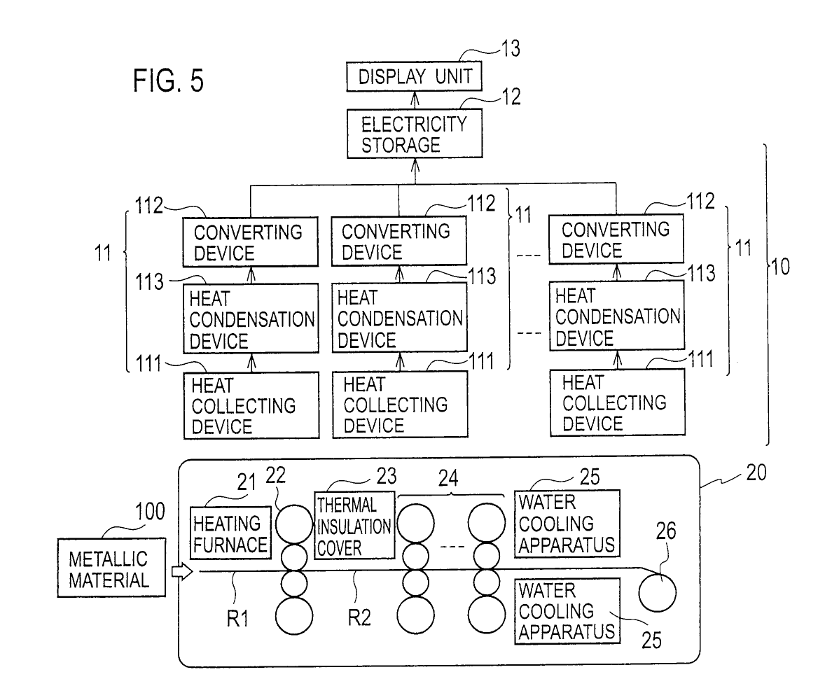

As shown in FIG. 5, a heat recovery system 10 according to a third embodiment of the present invention is different from the heat recovery system 10 of FIG. 1 in further including heat condensation devices 113 condensing heat collected by the heat collecting devices 111. The converting devices 112 convert the heat condensed by the heat condensation devices 113 to electricity. The other configuration thereof is the same as that of the first embodiment shown in FIG. 1.

In the heat recovery systems 10 shown in FIGS. 1 and 4, the heat collecting devices 111 are installed directly near the metallic material 100 or product coils 200. These heat recovery systems 10 mainly recoverradiant heat from the metallic material 100 or product coils 200.

On the other hand, the heat recovery system 10 shown in FIG. 5 mainly recovers heat of convection instead of radiant heat from the metallic material 100 or product coils 200. Accordingly, the heat collecting devices 111 are disposed above the hot rolling line 20 or metallic material 100. For example, when the door of the heating furnace 21 is opened, heat within the heating furnace 21 goes out through the door, and the air above the door of the heating furnace 21 is very hot. Accordingly, the heat collection can be effectively performed especially on the upstream side of the hot rolling line 20 where the metallic material 100 is hotter, including space above the door of the heating furnace 21 or space above the roughing mill 22.

For the aforementioned purpose, it is preferable that the heat collecting devices 111 have such a shape that heat of convection can be effectively collected. For example, each of the heat collecting devices 111 can be tapered upward like an open umbrella. The converting devices 112 are individually attached to the top narrow part.

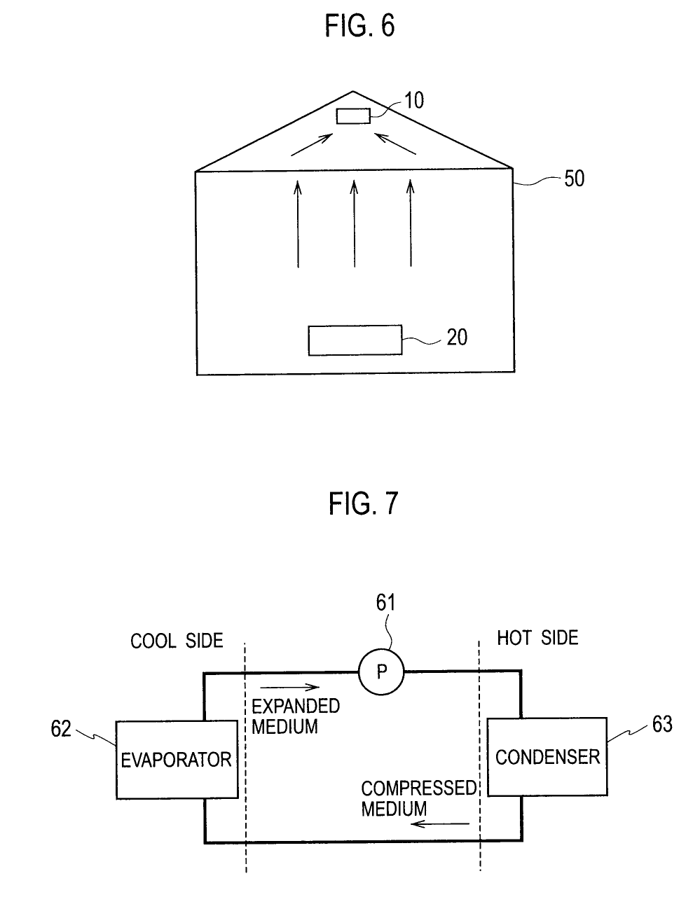

The heat recovery system 10 shown in FIG. 5 uses that heat radiating from the metallic material 100 and heat leaking from the heating furnace 21 always rise as a phenomenon of convection. The heat collecting devices 111 therefore need to be installed at high places. The heat collecting devices 111 are installed several meters above the hot rolling line 20 or the product coils 200 or are installed near the ceiling of the building which houses the hot rolling line 20 and product coils 200. The height of the ceiling is 20 m to 30 min some cases. For example, as shown in FIG. 6, if a building 50 housing the hot rolling line 20 has a triangular roof, the heat recovery system 10 is installed near the top of the ceiling into which heat is more likely to flow. This enables efficient heat recovery. In FIG. 6, the metallic material 100 is conveyed in the direction perpendicular to the paper surface. Arrows shown in FIG. 6 indicate a flow of heat.

Furthermore, to raise the temperature of the hot air collected by the heat collecting devices 111, the heat condensation devices 113 are individually provided between the heat collecting devices 111 and respective converting devices 112. As apart of each heat condensation device 113, a heat pump can be used.

Generally, heat moves from a high-temperature body to a low-temperature body. The heat pump can reverse the direction of such a heat flow. FIG. 7 is a view briefly explaining the principle of the heat pump. Liquid becomes gas while drawing heat from the surroundings, and gas becomes liquid while supplying heat to the surroundings. Using this principle, a medium is compressed by a pump 61 and then turned into gas by an evaporator 62 to draw heat from the surroundings, thus cooling the surroundings. The medium expanded to the gas is liquefied by the condenser 63, thus supplying heat to the surroundings. By such a mechanism, the cool side is further cooled while the hot side is further heated. As the medium, although chlorofluorocarbon was used before, hydrochlorofluorocarbon is used recently. Heat pumps are used for refrigerators, air conditioners, and the like even at home.

The evaporator 62 shown in FIG. 7 is connected to the heat collecting device 111, and the condenser 63 is connected to the converting device 112. The converting device 112 can therefore obtain heat at a temperature higher than heat of the air collected by the heat collecting device 111, and the thermoelectric conversion efficiency can be increased.

Since hot air has the property of rising, the heat recovery system 10 is installed above away from the hot rolling line 20, thus efficiently recovering heat. The heat recovery system 10 shown in FIG. 5 can cover a wide range to which heat rises from the hot rolling line 20. Accordingly, even if there are a descaler and the like below, the heat recovery system 10 can recover heat without being inhibited by the descaler and the like. In the case of disposing the heat collecting device 111 directly near the metallic material 100, the installation location of the heat collecting devices 111 are limited to the places in good surrounding environments with no water splashing and the like. However, in the case of installing the heat collecting devices 111 and converting devices 112 above the hot rolling line 20 and metallic material 100, the installation locations thereof are not affected by such a surrounding environment.

As described above, the heat recovery system 10 according to the third embodiment collects heat rising from the hot rolling line 20. Accordingly, the heat recovery system 10 can convert heat to electricity without being affected by the environment of the hot rolling line 20. The others are substantially the same as those of the first embodiment, and the redundant description thereof is omitted.

### <Modifications>

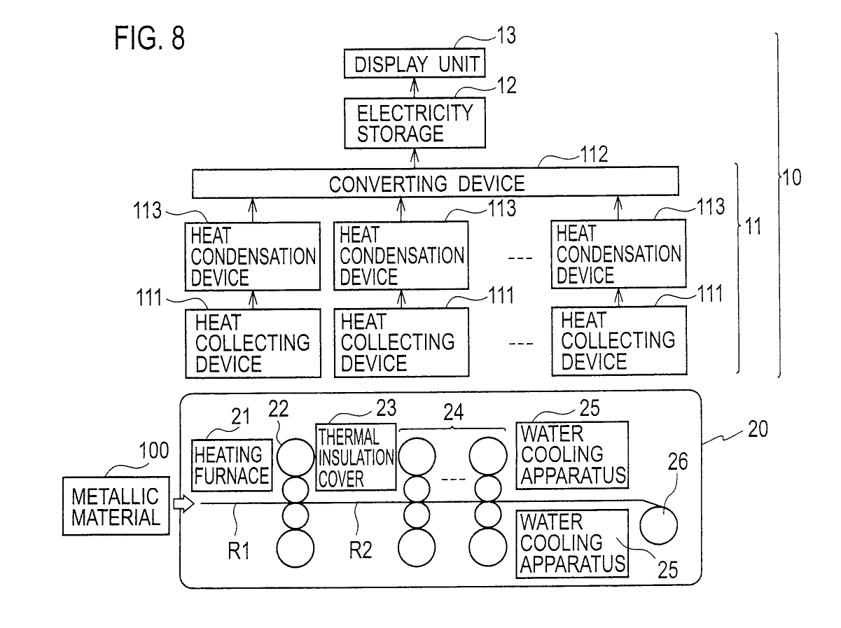

The heat collected above the hot rolling line 20 as described above is several tens ° C. when being collected by the heat collecting devices 111. Accordingly, the installation locations of the thermoelectric converters 11 are comparatively limited. In some cases, installing the heat collecting devices 111, converting devices 112, and heat condensation devices 113 as a unit as shown in FIG. 5 is not advantageous for cost reasons. As shown in FIG. 8, therefore, each converting device 112 is installed for a plurality of the heat collecting devices 111 and a plurality of the heat condensation devices 113 for consolidation of the converting devices 112. This can provide an effect of reducing the initial cost of the converting devices 112 and increasing the operating efficiency.

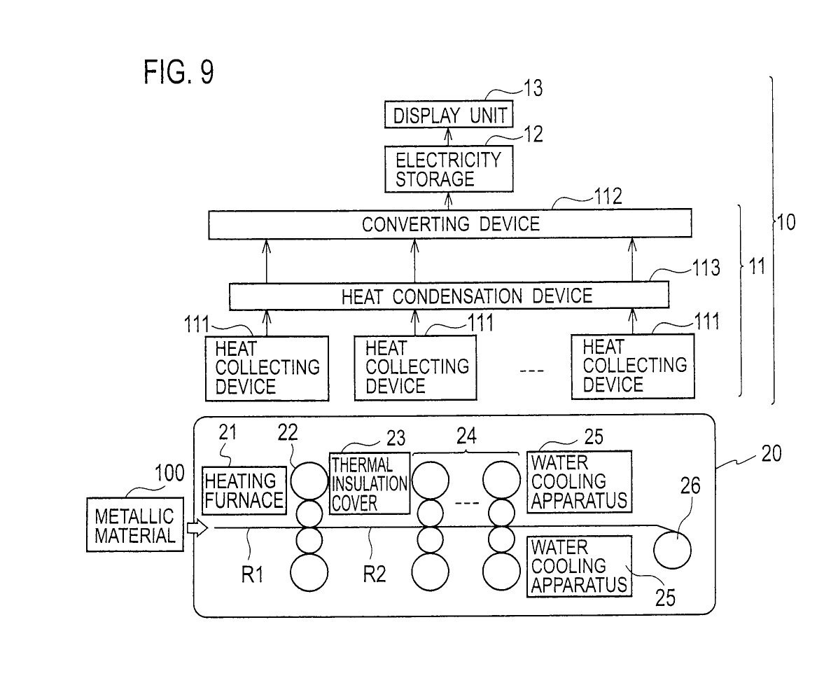

A heat recovery system 10 shown in FIG. 9 includes the heat condensation devices 113 consolidated in a similar way to the consolidation of the converting devices 112. Specifically, each heat condensation device 113 is provided for a plurality of the heat collecting devices 111.

### Fourth Embodiment

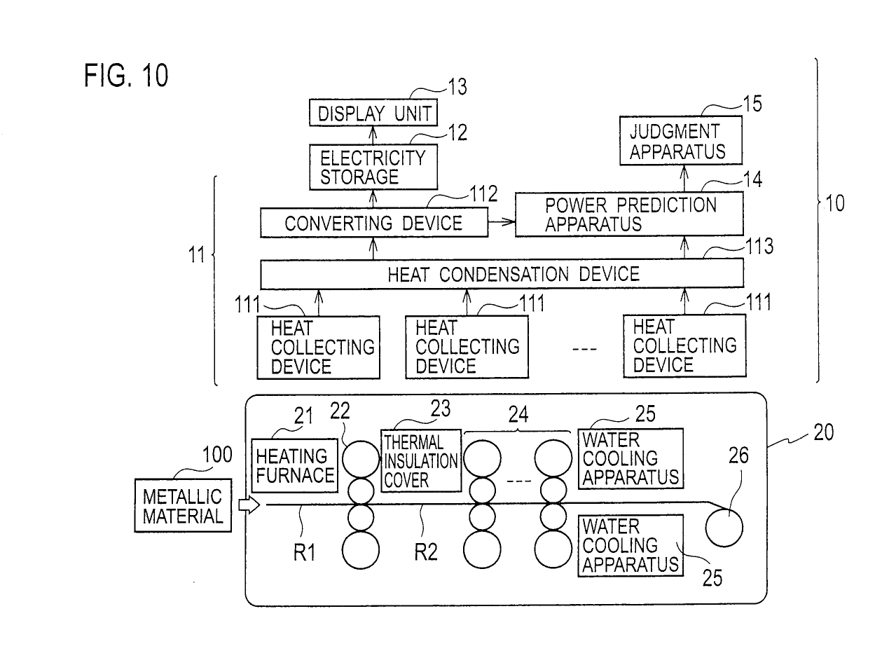

As shown in FIG. 10, a heat recovery system 10 according to a fourth embodiment of the present invention is different from the heat recovery system 10 shown in FIG. 9 in further including: a power prediction apparatus 14 predicting the amount of electricity generated by the converting devices 112 and the amount of electricity consumed by the heat condensation devices 113; and a judgment apparatus 15 determining based on the amounts of generated electricity and consumed electricity whether to perform heat recovery. The other configuration is the same as that of the third embodiment shown in FIG. 9.

The heat recovery system 10 according to the third embodiment does not always perform efficient thermoelectric conversion with the collected heat. This is because the heat condensation devices 113 consume electricity. For example, when each heat condensation device 113 includes a heat pump shown in FIG. 7, electricity for driving the pump 61 is necessary. The amount of electricity generated by the converting device 112 and the amount of electricity consumed by the heat condensation device 113 and the like are predicted. If the amount of consumed electricity exceeds the amount of generated electricity, the heat recovery system 10 should not be driven.

The way of predicting the amounts of electricity by the power prediction apparatus 14 can be, for example, compiling a database of past actual values of the amounts of generated electricity and consumed electricity and extracting predicted values of the amounts of generated electricity and consumed electricity from the database based on an index of the similar operation conditions.

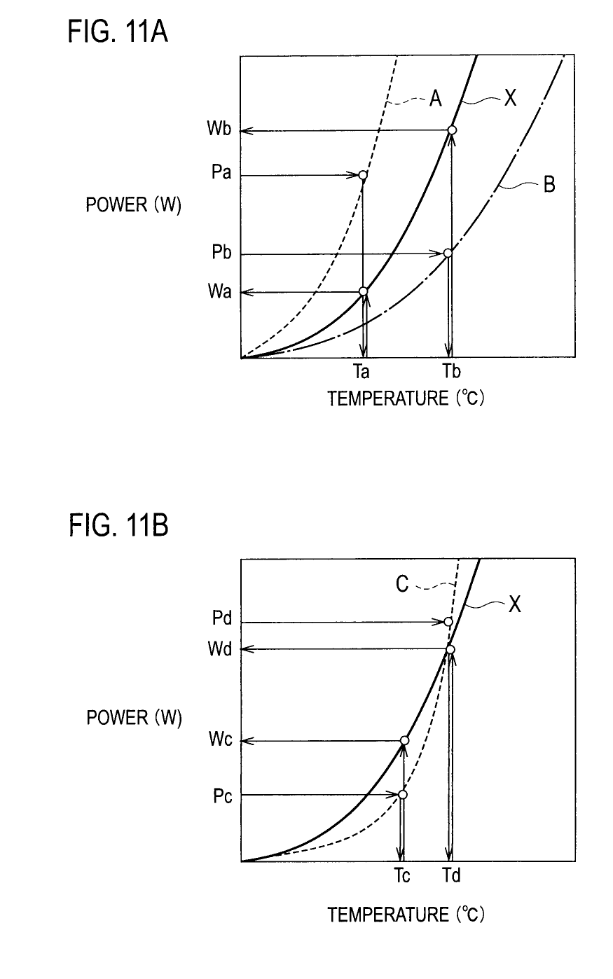

Alternatively, using efficiency curves shown in FIGS. 11A and 11B, the effectiveness of the heat recovery by the heat recovery system 10 can be determined based on the relationship between the amounts of generated electricity and consumed electricity. FIGS. 11A and 11B show that the operation of the heat recovery system 10 is effective when the amount of generated electricity exceeds the amount of consumed electricity based on the relationship between the thermoelectric conversion efficiency of the thermoelectric converters 11 and the efficiency of the heat pump. An efficiency curve X is the thermoelectric conversion efficiency curve of the thermoelectric converters 11.

FIG. 11A shows examples where the heat pump efficiencies are different. In the case of a heat pump efficiency curve A, although temperature Ta is obtained with an input power Pa, an output power Wa of the thermoelectric converters 11 is smaller than the input power Pa. There is no point in using the heat recovery system 10. On the other hand, in the case of a heat pump efficiency curve B, an input power Pb for providing temperature Tb is smaller than the output power Wb, and the use of the heat recovery system 10 is effective.

FIG. 11B shows a case where the difference between the heat pump efficiency indicated by a heat pump efficiency curve C and the thermoelectric conversion efficiency of the thermoelectric converters 11 varies on the operating region. When the heat pump is operated with input power Pc to provide temperature Tc, output power Wx of the thermoelectric converters 11 is larger than input power Pc. This means that the use of the heat recovery system 10 is effective. On the other hand, input power Pd for providing temperature Td exceeds output power Wd, and there is no point on using the heat recovery system 10.

Generally, the efficiency curve is previously known. The judgment apparatus 15 can determine whether to drive the heat recovery system 10 for heat recovery based on the relationship of the efficiencies. Instead of determining to perform heat recovery when the amount of generated electricity exceeds the amount of consumed electricity, the heat recovery system 10 may determine to perform the heat recovery when the difference between the amounts of generated electricity and consumed electricity exceeds a predetermined certain value. This means that a margin for judgment is introduced by using the predetermined certain value since the prediction of the amounts of generated electricity and consumed electricity involves errors.

The heat recovery system 10 shown in FIG. 10 is based on the configuration of the heat recovery system 10 shown in FIG. 9. However, the heat recovery system 10 may be based on the heat recovery system 10 shown in FIG. 5 or 8 and further include the power prediction apparatus 14 and judgment apparatus 15.

As described above, according to the heat recovery system 10 according to the fourth embodiment of the present invention, whether the operation of the heat recovery system 10 is effective or not can be determined based on the thermal condition of the metallic material 100 and the power consumption of the heat recovery system 10. This enables efficient recovery of heat generated from the metallic material 100 or product coils 200. The others are substantially the same as those of the third embodiment, and the redundant description thereof is omitted.

### Other Embodiments

It should not be understood that the description and the drawings, which form a part of the disclosure of the above-described embodiments, limit this invention. From this disclosure, a variety of alternative embodiments, examples and operation technologies will be obvious for those skilled in the art.

The description of the first to fourth embodiments shows examples where the hot rolling line 20 is a hot rolling line for thin plates. However, the present invention can be applied to various rolling lines for processing hot metallic materials such as rolling lines of thick plates, steel materials with various sectional shapes, steel bars, and wire rods as a heat recovery system collecting heat produced from the rolling line.

As described above, it is obvious that the present invention includes various embodiments and the like not described above. Accordingly, the technical scope of the present invention is determined by only the invention elements according to claims appropriate from the viewpoint of the above explanation.

What is claimed is:

1. A heat recovery system for a hot rolling line where a metallic material is heated and rolled, the system comprising:
a thermoelectric converter configured to convert heat generated by processing of the metallic material at the hot rolling line to electricity; and
an electricity storage configured to store the electricity converted by the thermoelectric converter.

2. The heat recovery system of claim 1, wherein the thermoelectric converter comprises:
a heat collecting device configured to collect the heat generated from the metallic material; and
a converting device configured to convert the heat collected by the heat collecting device to electricity.

3. The heat recovery system of claim 2, wherein the thermoelectric converter further comprises a heat condensation device condensing the heat collected by the heat collecting device, and
the converting device converts the heat condensed by the heat condensation device to electricity.

4. The heat recovery system of claim 3, wherein the heat collecting device is installed above the metallic material.

5. The heat recovery system of claim 3, further comprising:
a power prediction apparatus configured to predict an amount of electricity generated by the thermoelectric converter and an amount of electricity consumed by the heat condensation device; and
a judgment apparatus configured to determine whether to perform heat recovery based on the amount of generated electricity and the amount of consumed electricity.

6. The heat recovery system of claim 5, wherein the judgment apparatus determines to perform the heat recovery when the amount of generated electricity is more than the amount of consumed electricity or when the amount of generated electricity is a predetermined value more than the amount of consumed electricity.

7. The heat recovery system of claim 1, wherein the thermoelectric converter converts heat generated from the metallic material due to at least one of a plurality of processing steps conducted at the hot rolling line to electricity.

8. The heat recovery system of claim 1, wherein the thermoelectric converter converts heat which a product manufactured from the metallic material at the hot rolling line radiates due to processing at the hot rolling line to electricity.

9. The heat recovery system of claim 1, further comprising a display unit configured to display an amount of electricity stored in the electricity storage.
